(19) United States
(12) Patent Application Publication
(10) Pub. No.: US 2009/0275198 A1
(43) Pub. Date: Nov. 5, 2009

(54) Vapor Phase Methods for Forming Electrodes in Phase Change Memory Devices

(76) Inventors: Smuruthi Kamepalli, Rochester, MI (US); Tyler Lowrey, Rochester Hills, MI (US)

Correspondence Address: Kevin L. Bray;OVONYX, INC., 2956 Waterview Drive, Rochester Hills, MI, 48309, US

(21) Appl. No.: 12/113,586

(22) Filed: May 1, 2008

(51) Int. Cl. H01L 21/44

(52) U.S. Cl. 438/659; 438/667; 257/E21.597

(57) ABSTRACT

A method for forming electrode materials uniformly and conformally within openings having small dimensions, including sublithographic dimensions, or high aspect ratios. The method includes the steps of providing an insulator layer having an opening formed therein, and forming a conformal conductive or semiresistive material over and within the opening. The method is a CVD or ALD process for forming metal nitride, metal aluminum nitride, and metal silicon nitride electrode compositions. The methods utilize metal precursors containing one or more ligands selected from alkyl, allyl, alkene, alkyne, acyl, amide, amine, immine, imide, azide, hydrazine, silyl, alkylsilyl, silylamine, chelating, hydride, cyclic, carbocyclic, cyclopentadienyl, phosphine, carbonyl, or halide. Suitable precursors include monometallic precursors having the general formula MRₙ, where M is a metal, R designates a ligand as indicated above and n is an integer corresponding to the number of ligands bonded to the central metal atom. M may be Ti, Ta, W, Nb, Mo, Pt, Cr, Co, Ni, or other transition metal.

### FIELD OF INVENTION

This invention relates generally to programmable resistance and switching devices having one or more electrodes. More particularly, this invention relates to methods for forming electrodes for programmable resistance and switching device structures. Most particularly, this invention relates to formation of electrodes in confined regions to facilitate miniaturization of programmable resistance and switching devices.

### BACKGROUND OF THE INVENTION

Programmable resistance materials and fast switching materials are promising active materials for next-generation electronic storage, computing and signal transfer devices. A programmable resistance material possesses two or more states that differ in electrical resistance. The material can be programmed back and forth between the states by providing energy to induce an internal chemical, electronic, or physical transformation of the material that manifests itself as a change in resistance of the material. The different resistance states can be used to store or process data.

Fast switching materials are capable of being switched between a relatively resistive state (a quiescent low conduction state) and a relatively conductive state. Application of an energy signal, typically an electrical energy signal, induces the change from the relatively resistive state to the relatively conductive state. The relatively conductive state persists for so long as the energy signal is applied. Once the energy signal is removed, the switching material relaxes back to its quiescent state. Devices that incorporate switching materials are useful as voltage clamping devices, surge suppression devices, signal routing devices, and solid state memory access devices.

Phase change materials are a promising class of programmable resistance materials. A phase change material is a material that is capable of undergoing a transformation, preferably reversible, between two or more distinct structural states. In a common embodiment, a phase change material is reversibly transformable between a crystalline state and an amorphous state. In the crystalline state, the phase change material has lower resistivity; while in the amorphous state, it has higher resistivity. The distinct structural states of a phase change material may be distinguished on the basis of, for example, crystal structure, atomic arrangement, order or disorder, fractional crystallinity, relative proportions of two or more different structural states, a physical (e.g. electrical, optical, magnetic, mechanical) or chemical property etc. Reversibility of the transformations between structural states permits reuse of the material over multiple cycles of operation.

Typically, a programmable resistance material or switching device is formed by placing an active material, such as a phase change material, between two electrodes. Operation of the device is effected by providing an electrical signal between the two electrodes and across the active material. Programmable resistance materials may be used as the active material of a memory device. Write operations in a memory device, which may also be referred to herein as programming operations, apply electric pulses to the memory device. Read operations, which measure the resistance or threshold voltage of the memory device, are performed by providing current or voltage signals across the two electrodes. The transformation between the relative resistive state and relatively conductive state of a switching material is similarly induced by providing a current or voltage signal between two electrodes in contact with the switching material. One of the significant practical challenges that programmable resistance memory and switching devices face is to reduce the contact area of one or more electrodes contacting the active material. By reducing the contact area, the energy required to program a memory device or switch a switching device can be reduced and more efficient devices can be achieved.

Fabrication of semiconductor devices such as logic and memory devices typically includes a number of processes that may be used to form various features and multiple levels or layers of semiconductor devices on a surface of a semiconductor wafer or another appropriate substrate. Physical vapor deposition (PVD), chemical vapor deposition (CVD), and other deposition processes involving the reaction, decomposition or coating of gaseous, liquid, or solid precursors may be used in the formation of semiconductor devices. Lithography is a patterning process in the formation of semiconductor devices that is commonly used to define small-scale features and often sets a limit on the goal of device miniaturization. Additional semiconductor fabrication processes include chemical-mechanical polishing (CMP), etching, annealing, ion implantation, plating, and cleaning. In normal fabrication, an array containing a large number of semiconductor devices is formed on a semiconductor wafer.

In semiconductor device fabrication, it is desirable to reduce the length scale or feature size of devices as much as possible so that a greater number of devices can be formed per unit substrate area. As the feature size of devices is minimized, however, processing of the devices becomes more difficult. Small scale features become more difficult to define as the lithographic limit of resolution is reached and features that are defined become more difficult to process.

A common step in processing involves depositing a layer and forming an opening in it. Openings such as channels, trenches, holes, vias, pores or depressions in layers are commonly employed to permit interconnections between devices or layers of a structure. Typically, the opening is formed by lithography, then etching, and is subsequently filled with another material. As the dimension or length scale of an opening decreases upon miniaturization, it becomes increasingly difficult to fill the opening with another material without compromising performance or durability.

Techniques such as physical vapor deposition (PVD) or sputtering fail to provide dense or complete filling of openings when the dimensions of the opening are reduced below a critical size. Instead of providing a dense, uniform filling, these techniques increasingly incompletely fill openings as the feature size of the opening decreases. As the feature size decreases, there is a tendency for the packing density of the material formed in the opening to vary in the depth or lateral dimensions of the opening and as a result, the layer deposited within the opening may include voids, vacancies, gaps, pores, keyholes, or other non-uniform regions. Imperfections in the filling of openings become especially pronounced as the aspect ratio (ratio of the depth dimension to the lateral dimension of the feature) of the opening increases. Deep, narrow channels, for example, are more difficult to fill uniformly than channels that are shallow and wide. With deep, narrow features, sputtering and other physical deposition techniques are oftentimes unable to deliver sufficient material to the bottom of the feature. Instead, a layer of material is formed over or only near the top of the feature and the lower part of the feature is blocked and remains largely unfilled. Lack of structural uniformity in the filling of openings compromises performance because: (1) variations in device characteristics occur across an array due to differences in the degree or nature of filling non-uniformities from device-to-device and (2) less than optimal performance is achieved for each device due to the defective nature of the material within the opening.

Conformality of deposition is another processing difficulty that becomes exacerbated as feature size decreases. Fabrication of semiconductor devices generally involves forming a stack of layers, where the individual layers may differ in dimensions (lateral to or normal to the substrate) and compositions. The process of fabricating a semiconductor device generally involves sequential deposition of one layer upon a lower (previously formed) layer. Optimal device performance requires conformality of later-formed layers with earlier-formed layers. Each layer in a stack must conform to the shape and contours of the layer in the stack upon which it is formed. Smooth and uniform coverage is desired.

In addition to difficulties with achieving uniform filling, openings also present complications for achieving conformal deposition that become more pronounced as size of the opening decreases. The boundary or perimeter of an opening is frequently defined by an edge, step, or other relatively discontinuous feature. The shape of an opening is generally defined by a sidewall or perimeter boundary and a lower surface or bottom boundary. A trench opening, for example, is defined by generally vertical sidewalls and a bottom surface that is generally parallel to the substrate.

When fabricating semiconductor devices, it is often necessary to first form a layer with an opening and to subsequently deposit another layer over this layer. Conformality requires that the subsequent layer faithfully conform to the shape and texture of the underlying layer having the opening. The subsequent layer must deposit uniformly over both the portion of the underlying layer in which the opening has not been formed as well as over the opening itself. Conformality over the opening requires uniform coverage of the edges or steps that form the boundary of the opening. Achieving conformality over discontinuous features becomes increasingly difficult as the feature size of the opening decreases or the aspect ratio of the opening increases.

Fabrication of programmable resistance and switching devices often includes a step of forming an opening in a dielectric layer and filling the opening with a conductive material to form an electrical contact. Miniaturization of programmable resistance and switching devices requires methods for reducing the dimensions of the electrical contacts. Contacts with small dimensions are beneficial because the energy required to operate programmable resistance and switching devices decreases with decreasing contact size. Accordingly, it is desirable to develop techniques for forming and filling openings with small dimensions without suffering from the imperfections in filling and conformality associated with standard prior art techniques such as sputtering or physical vapor deposition. Ideally, the techniques would enable the fabrication of electrical contacts for programmable resistance and switching devices having dimensions near, at or below the lithographic limit.

Referring to the drawings, FIG. 1 depicts a representative structure of a phase change material device that illustrates the nature of imperfections that may form in an electrical contact having a sublithographic dimension when the contact is deposited via sputtering or physical vapor deposition. A conductive layer 106 is formed over a substrate 102. An insulative layer 110 having an opening formed therein is then formed over conductive layer 106. Lower electrical contact 128 is formed in the opening of insulative layer 110 using a physical vapor deposition process and CMP planarization. A layer of phase change material 114 is then deposited onto lower electrical contact 128 and a top electrode layer 116 is deposited over the phase change layer 114. Lower electrical contact 128 includes imperfections in the form of internal voids 120 and non-conformal region 112. The imperfections detract from device performance.

To improve the quality of electrical contacts in high aspect ratio devices, new methods are needed. The methods must provide more uniform filling of the openings in which the electrical contacts are formed as well as greater conformality with underlying and surrounding layers than the prevailing methods.

### SUMMARY OF THE INVENTION

The instant invention provides electronic devices having logic, memory, switching, or processing functionality based on programmable resistance materials, switching materials or other active materials and methods of fabricating same.

In accordance with one embodiment of the instant invention, a programmable resistance or switching device includes a substrate with a plurality of stacked layers including a bottom electrode layer, an insulator layer having an opening formed therein that exposes the bottom conductive layer, a lower electrode plug or liner formed in the opening by deposition and planarization, an active material deposited over the electrode plug and over the insulative layer, and a top electrode layer deposited over the active material.

The active material may be a programmable resistance material, switching material or other electronic material. Representative active materials include chalcogenide materials, phase-change materials, and threshold switching materials.

In one embodiment, one or more electrodes include a conductive or semi-resistive material where at least a portion of the electrode occupies or fills the opening. The electrode may be a plug electrode, a sidewall electrode (e.g. ring or liner), a rectilinear electrode, or a planar electrode and may also function as a resistive heater. The electrode may be a single layer or composite electrode that includes multiple layers or regions. The electrode may be in electrical contact or communication with wordlines or bitlines to permit transfer or receipt of electrical signals from external circuits.

The opening may be round, elliptical, bent, rectilinear or other circumferential shape. In one embodiment, the opening is a circular hole that is filled or lined with an electrode material. In another embodiment, the opening is a trench that is filled or lined with an electrode material. The opening has an aspect ratio that ranges between 0.25 and 5.

The methods for forming the electrode material include chemical vapor deposition, atomic layer deposition, and selective deposition. The electrode formation methods are designed to selectively and conformally fill or occupy the opening with an electrode material. The methods reduce structural irregularities of the electrode material within the opening and thereby promote more uniform and higher density filling.

For a better understanding of the instant invention, together with other and further illustrative objects thereof, reference is made to the following description, taken in conjunction with the accompanying drawings and claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic depiction of a conventional two-terminal electronic device having defects in an opening region of the two terminal device.

FIG. 2 illustrates a composite structure of an electronic device with an active material layer having a conductive bottom composite electrode that conformally and uniformly fills an insulator or other surrounding layer through a chemical vapor deposition or atomic layer deposition process.

FIG. 3 illustrates a partial cross-sectional view of an electronic device with an active material layer including a substrate and a first stacked conductive lower contact layer, and a second stacked insulative layer on the deposited conductive first stacked lower control layer.

FIG. 4 is a schematic depiction of the electronic device shown in FIG. 3 having a lithographically formed opening within the insulative layer.

FIG. 5 is a schematic depiction of the electronic device shown in FIG. 4 further including an electrode material with voids or defects formed over the opening.

FIG. 6 illustrates an electronic device having a conductive layer formed by a CVD or ALD process according to the instant invention before planarization.

FIG. 7 is a schematic depiction of a pore cell device design and a filler plug cell device design.

FIG. 8 is a schematic depiction of a recessed filler plug cell device and a microtrench device.

FIG. 9 is a schematic depiction of two confined cell devices.

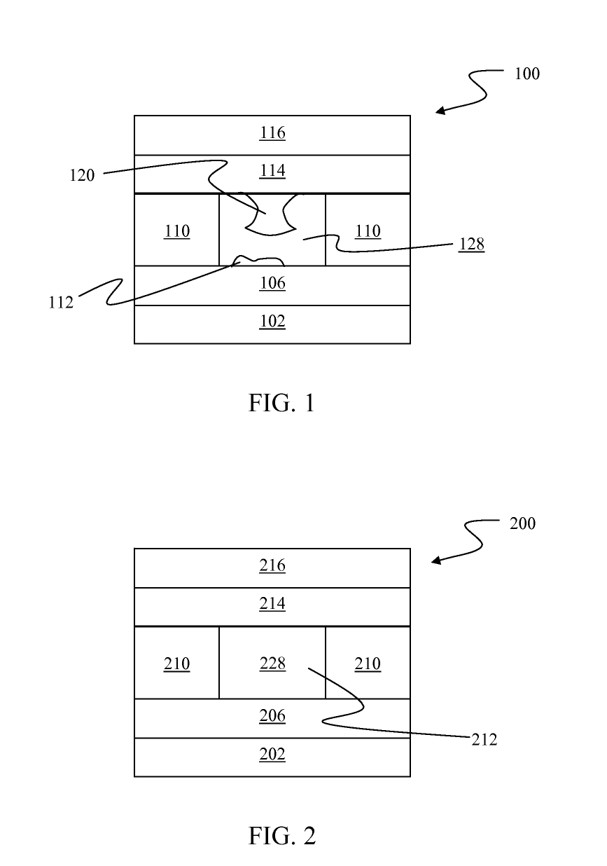

### DETAILED DESCRIPTION OF ILLUSTRATED EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The instant invention relates generally to electronic devices that include two or more electrodes in contact or electrical communication with an active material. As used herein, active material refers generally to an electrically stimulable material such as a programmable resistance material used for memory, programmable logic, or other applications; other memory material; or electrical switching material. A programmable resistance material is a material having two or more states that are distinguishable on the basis of electrical resistance. The two or more states may be structural states, chemical states, electrical states, optical states, magnetic states, or a combination thereof. A programmable resistance material is transformable (“programmable”) between any pair of states by supplying an appropriate amount of energy to the material. The supplied energy may be referred to as a “programming energy”. When transformed (“programmed”) to a particular state, the programmable resistance material remains in that state until additional energy is supplied to the material. The different states of a programmable resistance material are stable in the absence of external energy and persist for an appreciable amount of time upon removal of the source of programming energy. Programmable resistance materials include phase-change materials, chalcogenide materials, pnictide materials, and other multi-resistance state materials.

Phase change materials include materials that are transformable between two or more crystallographically-distinct structural states. The states may differ in crystal structure, unit cell geometry, unit cell dimensions, degree of disorder, particle size, grain size, or composition. Chalcogenide materials are materials that include an element from Column VI of the periodic table as a significant component along with one or more modifying elements from Columns III (e.g. B, Al, Ga, In), IV (e.g. Si, Ge, Sn), and/or V (e.g. Sb, Bi, P, As) of the periodic table. Pnictide materials are materials that include an element from Column V of the periodic table as a significant component along with one or more modifying elements from Columns ITT, IV, or VI of the periodic table. Many chalcogenide and pnictide materials are phase-change materials that are transformable between and among a plurality of crystalline, partially crystalline, and amorphous states. Other multi-resistance state materials include metal-insulator-metal structures with thin film insulators, or conductive oxide materials such as a family of CuO materials used in RRAM devices. Programmable resistance materials may serve as the active material in memory devices, including non-volatile memory devices. Representative programmable resistance materials in accordance with the instant invention are described in U.S. Pat. Nos. 5,543,737; 5,694,146; 6,087,674; 6,967,344; 6,969,867; 7,020,006; and references cited therein; all of which disclosures are incorporated by reference herein. These references also describe the basic operational characteristics of chalcogenide phase-change materials.

Electrical switching materials are materials that are switchable between two states that differ in electrical conductivity. The two states range in conductivity from the relatively resistive (e.g. comparable to a dielectric) to the relatively conductive (e.g. comparable to a metal). Electrical switching materials generally have a quiescent or relaxed state, usually a relatively more resistive state, in which they exist in the absence of electrical energy. When electrical energy is applied, the switching material transforms to the more conductive state and persists in that state transitorily for so long as it is subjected to a critical amount of energy from an external source. When the external energy decreases below the critical level, the switching material relaxes back to its quiescent state. Switching materials include OTS (Ovonic Threshold Switch) materials, negative differential resistance materials, and metal-insulator-metal structures. Certain chalcogenide and pnictide compositions exhibit electrical switching. Illustrative switching materials include those described in U.S. Pat. Nos. 6,967,344 and 6,969,867 incorporated by reference hereinabove.

FIG. 2 illustrates a typical structure of an electronic device 200 having two electrodes. The electrodes may also be referred to herein as contacts or electrical contacts. The main part of the structure of device 200 is formed as stacked layers on a substrate 202. The substrate 202 may be a silicon substrate or a substrate comprising other semiconductor materials. Substrate 202 may include a doped semiconductor material as well as access devices, power devices, or other electronic circuitry. The stacked layers include a lower conductive layer 206, a lower electrical contact 228 within opening 212 of an insulator layer 210, an electrically stimulable active layer 214, and an upper electrode layer 216. Electrical contact 228 is a restricted geometry electrode formed within opening 212 that is in electrical contact with lower conductive layer 206. Lower conductive layer 206 permits electrical communication between lower contact 228 and external circuitry. In one embodiment, lower conductive layer 206 may correspond to a grid line, such as a word line or a bit line of an array structure. Although upper electrode 216 is depicted as a blanket contact in FIG. 2, it may also be a restricted geometry electrode and may also be interconnected to other conductive layers such as a word line or a bit line of an array of devices.

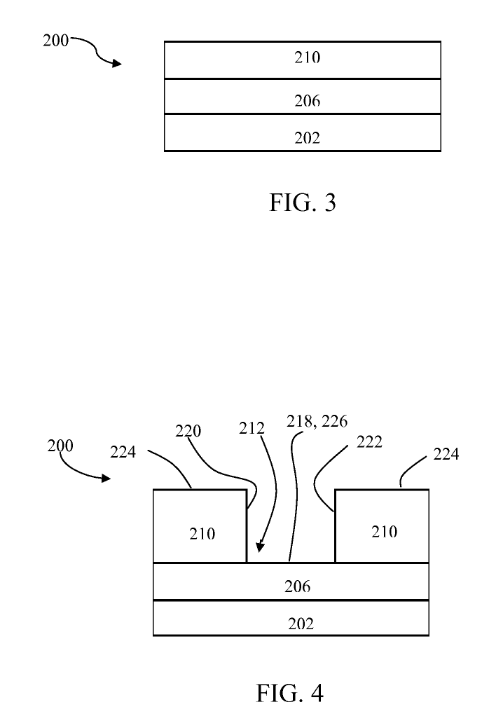

FIG. 3 shows a cross sectional view of the lower portion of device structure 200 at an intermediate stage of fabrication. The lower conductive layer 206 is formed on substrate 202 and insulator layer 210 is formed on lower conductive layer 206. Lower conductive layer 206 may be a metal, metal alloy or metal compound. Representative metals for lower conductive layer 206 include aluminum (Al), copper (Cu), tungsten (W), molybdenum (Mo), niobium (Nb), tantalum (Ta), rhenium (Re) or alloys thereof. The resistivity of lower conductive layer 206 may be controlled by varying the level of elements such as nitrogen or silicon incorporated in a metal or metal alloy. Compound materials that may be used to form conductive layer 206 include metal nitrides, metal chelates, organometallic compounds, or combinations thereof. Representative examples include TiN, TiSiN TiAlN, TiW, MoN, MoAlN, and MoSiN.

In one embodiment, lower conductive layer 206 is formed in a sputtering process and its resistivity may be adjusted by changing the nitrogen-to-metal ratio present in the growth environment. A greater nitrogen concentration will result in an increase in the resistivity. Alternatively, the resistivity of the lower conductive layer 206 may be adjusted by changing the silicon-to-metal ratio. A greater silicon concentration will result in an increase in the resistivity. Reactive sputtering of metals in a nitrogen or oxygen atmosphere permits control over the resistivity of lower conductive layer 206.

Insulator layer 210 provides electrical and thermal isolation of lower contact 228. Insulator layer 210 is generally an oxide, nitride or other dielectric material. Representative materials for insulator layer 210 include silicon oxides (e.g. SiO₂, SiOₓ), and silicon nitrides (e.g. Si₃N₄, SiNₓ). Insulator layer 210 may be formed using chemical or physical vapor deposition processes, including plasma-assisted processes.

Opening 212 in insulator layer 210 is formed and exposes a portion 218 of lower conductive layer 206 as shown in FIG. 4. Opening 212 has a predefined depth, width, and shape. Representative openings include depressions, pores, vias, trenches, holes, and channels. The openings may be formed by patterning and selectively removing portions of insulator layer 210. Standard photolithography, mask and etch, and reactive ion etching techniques may be used to form opening 212. Multiple openings 212 may be formed across a substrate to permit fabrication of an array of devices.

Insulator layer 210 and exposed portion 218 of lower conductive layer 206 cooperate to define the dimensions of the opening 212. Opening 212 includes sidewall surface 220, sidewall surface 222, and bottom 226 (which corresponds to the top surface of exposed portion 218 of lower conductive layer 206). The shape or cross-section of opening 212 may be controlled through the patterning process. The cross-sectional shape of opening 212 may be round (e.g. circular or elliptical), curved, linear, rectilinear (e.g. trench), polygonal, or bent. Accordingly, lower contact 228 may be round or non-round in shape and may form an enclosed or non-enclosed (e.g. arc, line, segment) structure. The full range of patterns and shapes of masks known in the art are within the scope of the instant invention. In the embodiment of FIG. 4, sidewall surfaces 220 and 222 may correspond to different sidewalls (e.g. the left and right sidewalls of a trench) or different portions of the same sidewall (e.g. opposing portions of a circular hole).

In an embodiment of the invention, the width or lateral dimension of opening 212 is at the lithographic limit. The lithographic limit is a feature size or physical dimension limit imposed by photolithographic processing capabilities. The lithographic limit is normally attributable to a limit on the ability to reduce the wavelength of the light source used to pattern or segment features during processing. According to the current technology roadmap, the feature size limit for flash technology is 65 nm (NOR)/57 nm (NAND). As processing techniques improve, the feature size limit will decrease in the future to further the goal of miniaturization. The projected feature size limit is 45 nm (NOR)/40 nm (NAND) in 2010 and 32 nm (NOR)/28 nm (NAND) in 2013. The methods described herein for forming contacts will scale and maintain their efficacy as the feature size limit decreases in the future.

In another embodiment, the width or lateral dimension of the opening 212 is sublithographic. An opening with sublithographic dimensions may be formed by first forming an opening with at or near a minimum lithographic dimension and then depositing a sidewall layer disposed within the opening to narrow its dimensions. An opening with sublithographic dimensions may also be formed, in another example, by forming a dielectric material on an underlying substrate, etching the dielectric material to expose a sidewall surface, forming a sacrificial layer having a thickness below the lithographic limit on the sidewall surface, anisotropically etching the sacrificial layer to remove the horizontal portions thereof, forming a dielectric layer over the remaining vertical portion of the sacrificial layer, planarizing to expose the top surface of the vertical sacrificial layer, and removing the vertical sacrificial layer to form an opening. In this latter method, the dimensions of the opening are controlled by the thickness of the deposited sacrificial layer and this thickness can readily be made to be well below the lithographic limit using many deposition techniques (e.g. chemical vapor deposition or atomic layer deposition).

In one embodiment, the width or lateral dimension of opening 212 is less than 1000 Å. In another embodiment, the width or lateral dimension of opening 212 is less than 600 Å. In yet another embodiment, the width or lateral dimension of opening 212 is less than 300 Å. The width or lateral dimension of the opening 212 is generally the physical dimension of the opening in a direction parallel to the substrate 202. In FIG. 4, for example, the width or lateral dimension is the distance between sidewall 220 and sidewall 222. When the shape of the opening is round, the lateral dimension may be the diameter or the equivalent thereof of the opening.

The aspect ratio of opening 212 may be defined as the ratio of the height or normal dimension of the opening to the width or lateral dimension of the opening. The height or normal dimension of the opening 212 is generally the physical dimension of the opening perpendicular to the substrate 202. In FIG. 4, for example, the height or normal dimension of the opening 212 corresponds to the thickness of insulative layer 210. In one embodiment of the instant invention, height or normal dimension of the opening 212 is at least 100 Å. In another embodiment of the instant invention, height or normal dimension of the opening 212 is at least 500 Å. In yet another embodiment of the instant invention, height or normal dimension of the opening 212 is at least 1000 Å. In one embodiment of the instant invention, the aspect ratio of the opening 212 is at least 0.5:1. In another embodiment of the instant invention, the aspect ratio of the opening 212 is at least 2:1. In yet another embodiment of the instant invention, the aspect ratio of the opening 212 is at least 4:1.

Opening 212 is filled in accordance with the instant invention with an electrical contact material 228 to form device structure 200 (see FIG. 2). Electrical contact 228 may be a single homogeneous layer of a conductive or semiresistive material or a combination of two or more layers differing in composition and/or resistivity. Electrical contact 228 is generally a metal, metal alloy, or metal compound. Examples of suitable electrical contact materials include refractory metals (e.g. Ni, Co, Cr, Pt, Ti, Ta, W, Mo, Nb), alloys of refractory metals (e.g. PtIr), nitrides of refractory metals (e.g. MoN, TiN, TiAlN, TiSiN, TiCN, TiSiC, TaN, TaCN, TaSiN, WN, WSiN, NbN), carbon, nitrogenated carbon, and dual layer metal and metal nitride combinations (e.g. Ti/TiN). In one embodiment, a dual layer structure is formed within an opening in which a first layer formed over the sidewall of the opening acts as a diffusion barrier layer and a second layer is formed within the first layer. The diffusion barrier layer acts to prevent atomic migration or exchange of mass between the inner second layer and the material of the layer in which the opening is formed. Metal nitrides (e.g. TiN) often serve as barriers to prevent the diffusion or migration of metals (e.g. W).

As indicated hereinabove, incorporation of nitrogen in metal or metal alloy compositions permits control over the resistivity of electrode materials. Resistivity control is desirable for active materials that operate at least partially via a thermal mechanism. In the case of phase-change materials, for example, formation of an amorphous phase state from a crystalline phase state requires local temperatures that are sufficient to melt the material. A resistive contact 228 creates thermal energy locally due to Joule heating as current passes through the device and provides an efficient source of programming energy.

By forming electrical contact 228 in a reduced dimensionality opening, it is possible to reduce the area of electrical communication between electrical contact 228 and active layer 214. The reduced area of electrical communication is beneficial because it permits operation of the device at lower currents. The reduced area of electrical contact 228, for example, more effectively channels external programming currents received by lower conductive layer 206. Confined electrical contact 228 delivers the operating current to a more controlled and spatially-limited region of electrically stimulable active material 214. The effective volume of active material 214 transformed by the operating current is reduced and the overall energy required to operate the device is decreased as current loss and heat loss to portions of electrically stimulable active layer 214 not essential to programming are minimized. Once the opening 212 is filled and planarized, a chalcogenide or other electrically stimulable active material layer 214 is deposited over the upper surfaces of insulative layer 210 and upper surface of deposited layer 228, and a top electrode layer 216 is formed on top of electrically stimulable active material layer 214.

In order to realize the benefits of a reduced area of electrical communication, it is necessary that electrical contact 228 fills or occupies opening 212 in a uniform fashion, without voids or gaps, and that electrical contact 228 adheres as conformally as possible to the exposed top surface 218 of lower conductive layer 206 and sidewall surfaces 220 and 222 (see FIG. 4). Voids, gaps, non-conformalities and other defects, whether internal to electrical contact 228 or at an interface of electrical contact 228 with a surrounding material, can lead to undesirable contact resistances at the top and bottom surfaces of electrical contact 228 and represent features that can vary over time or with cycling to impair device endurance or reliability.

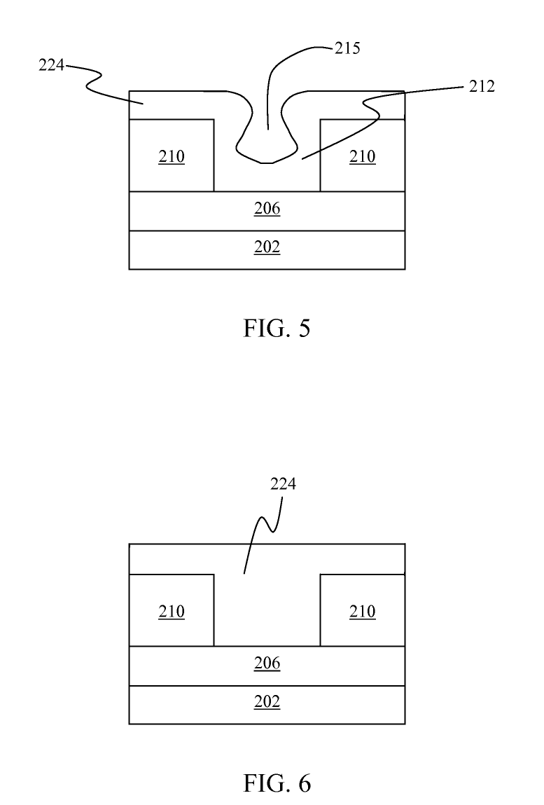

As discussed hereinabove, physical vapor deposition (e.g. sputtering) is a widely used method for forming electrical contacts. The method is advantageous because of its simplicity and versatility over a wide range of electrode compositions, but suffers from the tendency to form layers having voids and non-conformalities. These tendencies become more pronounced as the aspect ratio of the feature in which deposition occurs increases and are primarily attributable to the line-of-sight nature of deposition. FIG. 5 shows the structure of FIG. 4 after deposition of conductive layer 224 via a non-conformal deposition technique (before planarization). Conductive layer 224 is formed within opening 212 and on the top surface of insulator layer 210. Conductive layer 224 includes one or more voids 215 that impair the performance and durability of conductive layer 224 to serve as an electrode 228 after planarization. Better techniques are needed to realize the benefits of reduced dimensionality electrodes.

In co-pending U.S. patent application Ser. No. 11/880,587 (“'587 application”), the disclosure of which is incorporated by reference herein, liquid phase methods for filling openings with conductive materials were described. Methods discussed in the '587 application include dip coating, electroplating, electroless plating, and selective deposition. These methods were shown to provide more uniform filling of openings and greater conformality of the fill material with surrounding layers in the structure. In this application, further methods of filling or disposing materials within reduced dimensionality or high aspect ratio features such as opening 212 are described. The methods include chemical vapor deposition, atomic layer deposition, and selective deposition.

Chemical vapor deposition, hereinafter referred to as CVD, is a widely used technique for the synthesis of materials. In the CVD process, precursors of the constituent elements of a material are reacted to produce a thin film on a substrate. The reaction of the CVD precursors occurs either homogeneously in the gas phase or heterogeneously at the solid-gas interface of the substrate surface. Precursors for many elements are available and a variety of thin film compositions can be synthesized using CVD. In an embodiment of the instant invention, electrode materials are deposited into features using CVD. As used herein, CVD refers to all forms of chemical vapor deposition, including metalorganic chemical vapor deposition (MOCVD) and plasma enhanced chemical vapor deposition (PECVD).

In CVD processing, precursors are introduced into a reactor in gas phase form. Precursors that are in the gas phase at room conditions or upon heating are directly introduced into the reactor, typically in diluted form via a carrier gas. Liquid and solid phase precursors are vaporized or sublimed and then introduced into the reactor, also typically in diluted form in the presence of a carrier gas. Upon introduction into the reactor, precursors containing the chemical constituents of the desired material are reacted or decomposed (thermally, photochemically, or in a plasma) to form a thin film of desired composition on a substrate or underlying structure. The rate of deposition, stoichiometry, composition and morphology of the film can be varied through appropriate control over process parameters such as reaction temperature; substrate; selection of precursors; reactor pressure; and the rate of introduction of precursors into the reactor. CVD offers the advantages of providing high purity thin films at relatively low temperatures. Since CVD precursors or intermediates have molecular dimensions, they can readily access the recessed portions of high aspect ratio features. As a result, CVD processes promote dense, uniform filling of openings. CVD processes are also conformal in nature and provide smooth coverage of underlying, sloped, vertical walled, and adjacent surfaces.

FIG. 6 illustrates the improved conformality of electrical contact material 224 in an as-deposited state (relative to FIG. 5) when formed by a CVD (or ALD) process according to the instant invention. After planarization, the balance of the device 200 shown in FIG. 2 may be formed by first firming electrically stimulable active material 214 over electrical contact 228 and insulator 210 and then forming top electrode layer 216. Electrically stimulable active material layer 214 and top electrode layer 216 may be fabricated using physical vapor deposition, chemical vapor deposition, selective deposition, solution phase deposition or other conventional techniques. Electrically stimulable active material layer 214 may include phase change material, chalcogenide material, programmable resistance material, threshold switching material, or a combination thereof.

In the instant invention, several CVD processing strategies are employed to form electrode materials. For single element conductive materials, a precursor containing the desired element (normally a metal or carbon) is reacted or decomposed to form electrical contact 228 within opening 212 (FIG. 2). For multiple element conductive materials (e.g. metal alloys, metal carbides, metal nitrides, metal silicides), various deposition approaches may be used. In one embodiment, a multi-element electrode material is prepared through a direct CVD process, in which precursors for each element of the ultimate thin film material are introduced simultaneously into a CVD reactor and reacted.

In another embodiment, precursors for each element of a multi-element electrode material are introduced individually in a sequentially or alternating fashion. A precursor for a first element, for example, may be reacted or decomposed in the reaction chamber to form a sublayer comprising the first element on the substrate and subsequently a precursor for a second element may be reacted or decomposed on the sublayer comprising the first element to form a layer comprising two elements. This sequential deposition process can be repeated several times to build up a layer having a desired thickness. The relative amounts of the two elements can be controlled by controlling the reactivity of the precursors (e.g. through chemical composition of the precursor) and/or the conditions (e.g. temperature, pressure, time) of deposition of each of the precursors.

In still another embodiment, two or more elements of the desired electrode composition may be incorporated in and deposited from a single precursor. In a single source precursor embodiment, all elements of the desired electrode composition are incorporated within a single precursor and are deposited in the growing electrode layer upon decomposition or reaction of the precursor. In other embodiments, a precursor including at least two, but less than all, of the elements of the desired electrode composition is reacted or decomposed with one or more additional precursors that include the balance of the elements required for the desired electrode composition.

In a further embodiment, a layer including less than all of the elements required for the desired electrode composition is formed and subsequently subjected to a post-formation gas phase surface treatment to supply one or more additional elements. In one embodiment, a metal or metal alloy layer is formed and subsequently treated to a surface nitridization process (e.g. by exposing the surface to a nitrogen source gas such as ammonia) to form a metal or metal alloy nitride electrode composition. In another embodiment, a metal or metal alloy layer is formed and subsequently treated to a surface silicidization process (e.g. by exposing the surface to a silicon source gas such as silane or disilane) to form a metal or metal alloy silicide electrode composition.

When multiple elements are deposited (whether simultaneously or sequentially), a post-deposition processing step (e.g. annealing) may optionally be performed to finalize the reaction or homogenize the as-deposited electrode material. When the instant electrode is prepared through an alternating CVD process, for example, a penultimate multilayer structure is deposited where each of the alternately deposited layers includes a different subset of the elements to be included in the intended ultimate composition. A post-CVD processing step, typically a thermal processing step, may be used to induce a transformation of the penultimate multilayer structure into the ultimate electrode composition.

When two or more precursors are introduced simultaneously into the CVD reactor, the complexity of the process increases due to the need to insure comparable rates of reaction or decomposition of the different precursors in the reaction environment. When a multi-element material is prepared, it is beneficial for the different precursors to provide the necessary elements at similar rates so that more nearly uniform and homogeneous thin films are formed. If one precursor reacts at a significantly faster rate than other precursors, the possibility arises that a film of non-uniform or unintended composition forms. A faster reacting precursor, for example, may deposit a mono-elemental layer onto the substrate before appreciable reaction or decomposition of slower reacting precursors has occurred. As a result, the stoichiometric ratio desired in the deposited material may be lacking. In the case of ternary and higher compositions, preferential reactions between a subset of the precursors may also occur and lead to the formation of a thin film that is depleted with respect to the element(s) of the non-preferentially reacting precursor(s). A further complication arises if the elements (or reactive species containing the elements) desired in the deposited film differ appreciably in volatility. Volatility is a relevant consideration because surface desorption of the desired elements (or species containing the desired elements) can occur during CVD deposition. If the different elements of a multi-element composition desorb or volatilize at appreciably different rates from the surface, the intended stoichiometry may not be achieved.

Most precursors include a central element (or elements) that one intends to incorporate into a CVD thin film along with pendant groups that are bonded to the central element. Many precursors, for example, include a central metal or non-metal atom that is bonded by one or more ligands. During deposition, it is generally necessary for the ligands to sever and/or decompose during the formation of the reactive intermediate that delivers the central element to the growing film. The bond strength between the ligands and the central atom is typically an important contributing factor in the rate of reaction or decomposition of the precursor. Through judicious control of the ligands, the selectivity of a precursor with respect to the incorporation the desired elements in the deposited thin film can be optimized and the incorporation of impurities from the ligands can be minimized. Chemical tuning of CVD precursors provides control over the relative rates of decomposition, reaction, and desorption of the different elements in a multicomponent material. Chemical tuning also provides control over the volatility of the precursor for delivery into the CVD reactor. From the standpoint of process convenience, it is generally desirable for CVD precursors to be high vapor pressure liquids.

ALD (Atomic Layer Deposition) is a variant of CVD in which vapor phase precursors are introduced separately in an alternating sequence to build up the desired composition. In a typical ALD process, a precursor containing a first element of the desired composition is pulsed into the reactor for a fixed duration to deposit a layer of the first element on the substrate. The reactor is then purged with a pulse of an inert gas and a precursor containing a second element of the desired composition is pulsed into the reactor to deposit a layer of the second element. A second inert gas purge is then applied and the process is continued for each element of the desired composition. Multiple sequential cycles are completed to form the desired thickness of the desired composition. In each ALD cycle, the objective is to control the time of exposure of each precursor to insure saturative coverage and self-limited growth on the underlying growth surface. In this way, the composition can be controlled on the monolayer level and materials with precise compositions and thicknesses can be prepared through a repetitive sequence of precursor pulses. The intended stoichiometry can be achieved by controlling the number and order of precursor pulses for each desired element over a series of ALD cycles. By introducing different precursors separately and purging with an inert gas, ALD avoids potentially undesirable gas phase reactions between precursors. Precursors suitable for CVD deposition are often suitable for ALD deposition.

Precursors that can be used to form uniform or conformal electrodes within high aspect ratio features in a CVD or ALD process include mono- or multi-metallic complexes or compounds with one or more ligands R selected from one or more of the following groups of ligands: alkyl, allyl, alkene, alkyne, acyl, amide, amine, immine, imide, azide, hydrazine, silyl, alkylsilyl, silylamine, chelating, hydride, cyclic, carbocyclic, cyclopentadienyl, phosphine, carbonyl, or halide. Suitable precursors include monometallic precursors having the general formula MRₙ, where M is a metal, R designates a ligand as indicated above and n is an integer corresponding to the number of ligands bonded to the central metal atom. M may be Ti, Ta, W, Nb, Mo, Pt, Cr, Co, Ni, or other transition metal. M may also be a post-transition metal such as Al. The ligands R included in a precursor may be of the same type or different type and may include combinations of two or more types of ligands from within the same class or different classes of ligands indicated above. The number of ligands n depends on the metal M and generally ranges from 2-6. In one embodiment, n is equal to the formal oxidation state of the metal M. Further precursors include bimetallic precursors having the general formula MM′Rₙ, where R and n are as described above and M and M′ are metals. M and M′ may be the same or different metals.

Metal nitride electrode materials may be formed by reacting a nitrogen precursor with one or more metal precursors in a CVD or ALD process. Nitrogen precursors include nitrogen gas, ammonia, amines having the general formal NR₃, and hydrazine (N₂H₄), diazene (N₂H₂) or an alkyl substituted hydrazine (N₂H₄₋ₓR′ₓ) or diazene (N₂H₂₋ₓR′ₓ). The different ligands R or R′ within each nitrogen precursor may be the same or different chemical groups.

In a representative example, a metal nitride may be formed by reacting a metal amide with ammonia or an amine. In an illustrative embodiment, TiN can be prepared by a reaction of a titanium amide precursor (TiR₄₋ₓLₓ, where L is an amide ligand (e.g. dimethylamide)) with ammonia. Similarly, MoN can be prepared by a reaction of a molybdenum amide precursor (MoR₄₋ₓLₓ, where L is an amide ligand) with ammonia. Analogous reactions occur for W, Ta, Ni, Co, Cr, Pt, and Nb. A metal nitride may also be formed by reaction or decomposition of a metal amine or metal azide. In an illustrative embodiment, TiN can be prepared by a reaction or decomposition of a titanium azide (R₄₋ₓTiLₓ, where L is an azide (N₃) ligand) or titanium amine (R₄₋ₓTiLₓ, where L is an amine (NR₃) ligand). Analogous reactions occur for Mo, W, Ta, and Nb as well. The reaction or decomposition may occur in the presence or absence of ammonia to provide further control over the level of nitrogen in the final film.

In a further example, a metal nitride can be prepared by first reacting or decomposing a metal precursor to form a metal layer and then subjecting the metal layer to a nitridization process. In an illustrative embodiment, TiN can be prepared by reacting or decomposing a titanium alkyl (TiR₄) to form a Ti layer and then subjecting the Ti layer to ammonia (NH₃), hydrazine (N₂H₄), diazene (N₂H₂) or other nitrogen precursor at an elevated temperature and/or in the presence of a plasma to form a TiN or nitrided Ti layer. The two-step process can be repeated multiple times to increase the thickness of the layer.

In another example, a metal aluminum nitride may be formed by reacting a metal amide with a trialkyl aluminum precursor and ammonia or an amine in a CVD or ALD process. In an illustrative embodiment, TiAlN can be prepared by a reaction of a titanium amide with trimethyl aluminum and ammonia. Similarly, MoAlN can be prepared by a reaction of a molybdenum amide with trimethyl aluminum and ammonia. Analogous reactions occur for W, Ta, Ni, Co, Cr, Pt, and Nb. A metal aluminum nitride may also be formed by reaction or decomposition of a metal amine or metal azide in the presence of a trialkyl aluminum precursor. In an illustrative embodiment, TiAlN can be prepared by reaction or decomposition of a titanium azide with trimethyl aluminum. Analogous reactions occur for W, Ta, Ni, Co, Cr, Pt, Mo, and Nb. The reaction or decomposition may occur in the presence or absence of ammonia to provide further control over the level of nitrogen in the final film.

In another example, a metal aluminum nitride can be prepared by reacting or decomposing a metal-aluminum precursor (RₓMAlR_{y}) in the presence of a nitrogen precursor. In an illustrative embodiment, TiAlN can be prepared by reaction or decomposition of a titanium-aluminum precursor (R₃TiAlR₂) in the presence of ammonia. Analogous reactions occur for W, Ta, Ni, Co, Cr, Pt, Mo, and Nb. When one or more ligands R is an amine, amide, imine, or other nitrogen-containing group, TiAlN can be prepared from a single precursor.

In another example, a metal silicon nitride can be prepared by reacting or decomposing a metal precursor with a silicon precursor and a nitrogen precursor in a CVD or ALD process. In an illustrative embodiment, TiSiN can be prepared by reacting a titanium alkyl precursor (TiR₄₋ₓLₓ where L is an alkyl ligand) with silane (SiH₄) or disilane (Si₂H₆) and ammonia. In another illustrative embodiment, TaSiN can be prepared by reacting a tantalum alkyl precursor (TaR₄₋ₓLₓ, where L is an alkyl ligand) with silane (SiH₄) or disilane (Si₂H₆) and ammonia. Analogous reactions occur for W, Mo, Ni, Co, Cr, Pt, and Nb.

In another example, a metal silicon nitride can be prepared by reacting or decomposing a metal-nitrogen precursor with a silicon precursor in a CVD or ALD process. In an illustrative embodiment, TiSiN can be prepared by reacting a titanium amine, titanium amide, titanium hydrazine, or titanium azide precursor (TiR₄₋ₓLₓ, where L is an amine (e.g. dimethylamine), amide (e.g. dimethylamide), hydrazine, or azide ligand) with silane or disilane. In another illustrative embodiment, TaSiN can be prepared by reacting a tantalum amine, tantalum amide, tantalum hydrazine, or tantalum azide precursor (TaR₄₋ₓLₓ, where L is an amine (e.g. dimethylamine), amide (e.g. dimethylamide), hydrazine, or azide ligand) with silane or disilane. Analogous reactions occur for W, Mo, Ni, Co, Cr, Pt, and Nb.

In another example, a metal silicon nitride can be prepared by reacting or decomposing a metal-silicon precursor with a nitrogen precursor in a CVD or ALD process. In an illustrative embodiment, TiSiN can be prepared by reacting a titanium silyl precursor (TiR₄₋ₓLₓ, where L is a silyl (SiR₃) ligand) with ammonia, an amine, hydrazine, or other nitrogen-containing gas. In another illustrative embodiment, TaSiN can be prepared by reacting a tantalum silyl precursor (TiR₄₋ₓLₓ, where L is a silyl (SiR₃ (e.g. Si(CH₃)₃) ligand) with ammonia, an amine, hydrazine, or other nitrogen-containing gas. Analogous reactions occur for W, Mo, Ni, Co, Cr. Pt, and Nb.

In another example, a metal silicon nitride can be prepared by reacting or decomposing a metal-nitrogen precursor with a metal-silicon precursor in a CVD or ALD process. The metal-nitrogen precursor may be a metal amine, metal amide, metal hydrazine, or metal azide. The metal-silicon precursor may be a metal complex that includes a silyl ligand. In an illustrative embodiment, TiSiN can be prepared by reacting or decomposing TiR₄₋ₓLₓ (where L is an amine (e.g. dimethylamine), amide (e.g. dimethylamide), hydrazine, or azide ligand and R is cyclopentadienyl or a C₁-C₃ alkyl) with TiR₄₋ₓLₓ (where L is a silyl ligand (e.g. Si(CH₃)₃) and R is cyclopentadienyl or a C₁-C₃ alkyl). Analogous reactions occur for W, Mo, Ni, Co, Cr, Pt, and Nb.

In another example, a metal silicon nitride can be prepared by reaction or decomposition of a single source precursor in a CVD or ALD process. The single source precursor includes a metal, silicon and nitrogen in a common molecular structure. Single source precursors include metal precursors with one or more silyl ligands in combination with one or more nitrogen-containing ligands (e.g. amines, amides, hydrazine, azide) as well as metal precursors that include one or more silylamine (NRₓ(SiR₃)₂₋ₓ) and/or aminosilyl (SiRₓ(NR₂)₃₋ₓ) ligands. In an illustrative embodiment, TiSiN can be formed from the reaction or decomposition of RₓTiL₄₋ₓ, where L is a silylamine ligand (e.g. N(C₂H₅)(Si(CH₃)₃) or N(Si(CH₃)₃)₂). In another illustrative embodiment, TiSiN can be formed from the reaction or decomposition of RₓTiL₄₋ₓ, where L is an aminosilyl ligand (e.g. Si(CH₃)₃(N(CH₃)₂) or Si(N(CH₃)ₓ)₄). In another embodiment, TiSiN can be formed from the reaction or decomposition of RₓTiQ_{y}L_{4-x-y}, where Q is a silylamine ligand (e.g. N(C₂H₅)(Si(CH₃)₃) or N(Si(CH₃)₃)₂) and L is an aminosilyl ligand (e.g. Si(CH₃)₃(N(CH₃)₂) or Si(N(CH₃)ₓ)₄). Analogous reactions occur for W, Ta, Ni, Co, Cr, Pt, Mo, and Nb.

In a further example, a metal silicon nitride can be prepared by first reacting or decomposing a metal precursor to form a metal layer, then subjecting the metal layer to a nitridization process, and then subjecting the nitrided metal layer to a silicidization process. In one embodiment, TiN can be prepared by reacting or decomposing a titanium alkyl (TiR₄) to form a Ti layer and then subjecting the Ti layer to ammonia (NH₃), hydrazine (N₂H₂) or other nitrogen precursor at an elevated temperature and/or in the presence of a plasma to form a TiN or nitrided Ti layer. The nitridization process is then followed by a silicidization process by reacting or decomposing silane or disilane with the TiN or nitrided Ti layer. These process steps can be repeated multiple times to increase the thickness of the layer and the order of the steps can be varied or reversed. Analogous reactions occur for W, Ta, Ni, Co, Cr, Pt, Mo, and Nb. Similarly, a metal silicon nitride layer can be formed by reacting or decomposing a metal-nitrogen precursor to form a metal nitride as described hereinabove and then subjecting the metal nitride to a silicidization process to form a metal silicon nitride. A metal silicon nitride layer can also be formed by reacting or decomposing a metal-silicon precursor to form a metal silicide and then subjecting the metal silicide to a nitridization process to form a metal silicon nitride.

As the foregoing examples indicate, metal nitride, metal aluminum nitride, and metal silicon nitride electrode materials can be prepared from a variety of precursors in a CVD or ALD process. The electrode materials can be prepared from reactions or decompositions of single source precursors or reactions or decompositions of two or more precursors, each of which includes at least one element of the desired composition. The reacting or decomposing precursors may be introduced in the reactor simultaneously or sequentially (with or without intervening purge). Intermediate compositions containing less than all of the elements of the intended composition may be formed by simultaneous reaction or decomposition of precursors containing a subset of intended elements and the resulting layer may then be treated in a gas-phase process through reaction or decomposition of precursors containing the balance of intended elements.

In forming nitrogen-containing electrode materials, it is desirable to have a high nitrogen to metal ratio as reflected by the molar proportions of different precursors containing the intended metal and nitrogen or by the ratio of nitrogen to metal in a single precursor. In metal-nitrogen precursors, individual ligands containing two or more nitrogen atoms (such as azide, bidentate amine, or hydrazine ligands) are one preferred embodiment. In one embodiment, the metal precursor includes an azide ligand and an amine ligand. In another embodiment, the metal precursor includes an azide ligand and a hydrazine ligand. In still another embodiment, the metal precursor includes a hydrazine ligand and an amine ligand. In a further embodiment, the metal precursor includes an azide or hydrazine ligand and a silylamine ligand. In an additional embodiment, the metal precursor includes an azide or hydrazine ligand and an aminosilyl ligand. In other embodiments, the metal precursor includes a nitrogen atom with a double bond. Examples include azide, imide, and imine ligands.

As indicated hereinabove, it is often desirable to control the resistivity of electrode materials to tailor the thermal environment of an electrically stimulable material adjacent to the electrode. Higher resistivity of the electrode produces higher local temperatures in the vicinity of the electrically stimulable material for a given current density. In one embodiment herein, resistivity of electrode materials produced according to the instant CVD and ALD methods is controlled by varying the nitrogen content of the electrode composition. It is generally expected that the resistivity of metal nitride, metal aluminum nitride, and metal silicon nitride electrode materials increases with increasing nitrogen content. Overstoichiometric inclusion of nitrogen in the electrode composition increases the resistivity. The level of nitrogen incorporation may be controlled by increasing the ratio of nitrogen precursor to metal precursor in the CVD or ALD deposition process. Alternatively, a dedicated nitridization step may be used to increase the nitrogen content of a deposited electrode material. The increased level of nitrogen may be uniform throughout the deposited electrode material or localized near the surface of the deposited electrode material.

In one embodiment, metal nitride compositions having the general formula MNₓ, where x>1 are prepared. In another embodiment, metal nitride compositions having the general formula MNₓ, where x>1.1 are prepared. In a further embodiment, metal nitride compositions having the general formula MNₓ, where x>1.25 are prepared. In another embodiment, metal aluminum nitride compositions having the general formula MAlNX, where x>1 are prepared. In another embodiment, metal aluminum nitride compositions having the general formula MAlNₓ, where x>1.1 are prepared. In a further embodiment, metal aluminum nitride compositions having the general formula MAlNₓ, where x>1.25 are prepared. In a further embodiment, metal silicon nitride compositions having the general formula MSiNₓ, where x>1 are prepared. In another embodiment, metal silicon nitride compositions having the general formula MSiNₓ, where x>1.1 are prepared. In a further embodiment, metal silicon nitride compositions having the general formula MSiNₓ, where x>1.25 are prepared.

The resistivity of electrode materials may also be controlled through the inclusion of O₂ or other oxygen-containing precursor in the growth environment of the instant CVD or ALD process. The presence of oxygen leads to the incorporation of oxygen and/or oxidation of the electrode composition to produce a more resistive material. Metals generally oxidize readily in the presence of an oxygen-containing precursor to form more resistive phases. By controlling the amount of oxygen in the growth environment, the level of oxygen incorporated in the electrode material can be controlled. Higher levels of oxygen incorporation lead to higher resistivity for the electrode material. Oxygen may also be incorporated by including oxygen as an element within one or more ligands bonded to a metal atom of a CVD or ALD precursor. Carbonyl, alkoxy, and keto ligands are illustrative of ligands that include oxygen. Oxygen incorporation may also be achieved using a post-deposition oxidation treatment. The instant invention further extends to the control of resistivity through the formation of oxynitride or other compositions that include both oxygen and nitrogen. Oxidation of metal nitride, metal aluminum nitride, and metal silicon nitride compositions is within the scope of the instant invention.

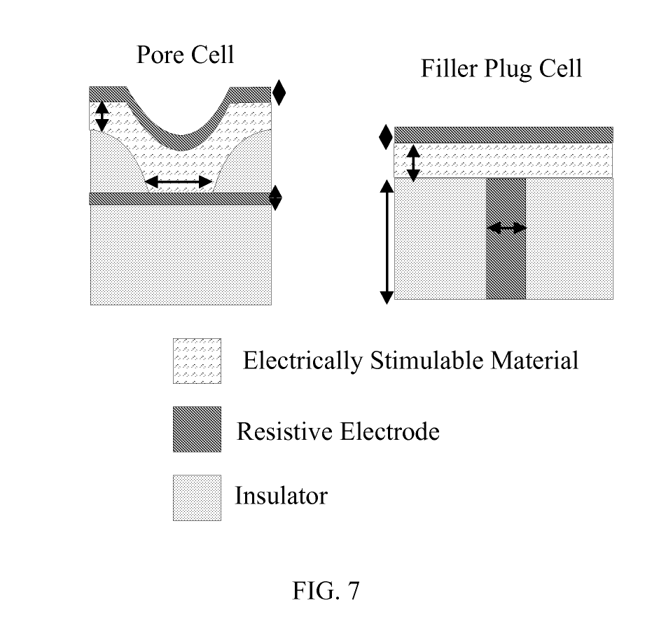

The instant CVD and ALD methods for forming electrodes within openings can be applied to any device structure having a low dimensional or high aspect ratio opening to obtain uniform, conformal filling. Representative device structures are illustrated in FIGS. 7-9, which show the central portion of devices that include an electrically stimulable material, resistive electrodes in electrical communication with the electrically stimulable material, and a surrounding insulator material. The electrically stimulable material, resistive electrodes, and insulator regions of the structure are separately indicated by distinctive shading as shown in each of FIGS. 7-9. The electrically stimulable material is a material that is responsive to an electrical current, voltage or field and includes programmable resistance materials, phase-change materials, chalcogenide materials, and switching materials as described hereinabove.

FIG. 7 shows devices based on the pore cell and filler plug cell designs. In the pore cell, the electrically stimulable material tapers to a narrowed area of contact with the lower resistive electrode and may include an irregularly shaped top surface upon which an upper resistive electrode must be formed. In the pore cell example shown in FIG. 7, the upper resistive electrode is formed over a depression of the top surface of the electrically stimulable material. A depression is an embodiment of an opening herein and in a pore cell, the shape, dimensions and aspect ratio of the depression may vary and come within the regime in which conventional electrode deposition techniques form electrodes with voids or other defects as described hereinabove. Application of the instant CVD or ALD techniques permits formation of upper resistive electrodes having greater structural uniformity within depressions. Similarly, the lower resistive electrode of the filler plug cell is typically formed within a high aspect ratio opening of a surrounding dielectric material and can be formed with greater uniformity and fewer defects using the instant CVD or ALD methods.

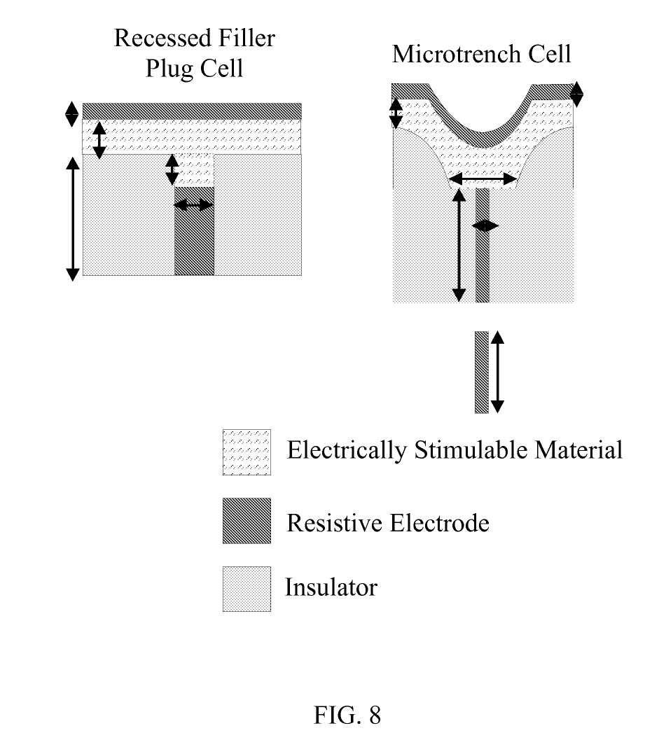

FIG. 8 shows the recessed filler plug cell design and the microtrench cell design. The recessed filler plug cell is a variation of the filler plug cell in which a portion of the electrically stimulable material is recessed into the high aspect ratio opening in which the lower electrode is formed. The instant invention includes an embodiment in which a plurality of layers is formed within an opening using the CVD or ALD methods described hereinabove. In this embodiment, a composite resistive electrode that includes layers of two or more materials or adjacent regions differing in resistivity may be formed via a sequential process in which a first resistive electrode material is formed via CVD or ALD and a second resistive electrode material is then formed via CVD or ALD. If the second resistive electrode material is adjacent to the electrically stimulable material and has a higher resistivity than the first resistive electrode material, the composite electrode more effectively localizes current-induced thermal energy in close proximity to the electrically stimulable material and provides more efficient operation. By way of example, a Ti layer may be formed and a TiN layer may subsequently be formed over the Ti layer. The microtrench cell is a variation of the pore cell design in which the lower resistive electrode is reduced in one or more lateral dimensions in order to minimize the lower contact area. Formation of either or both of the upper or lower resistive electrodes of the microtrench cell may occur via the instant CVD or ALD process.

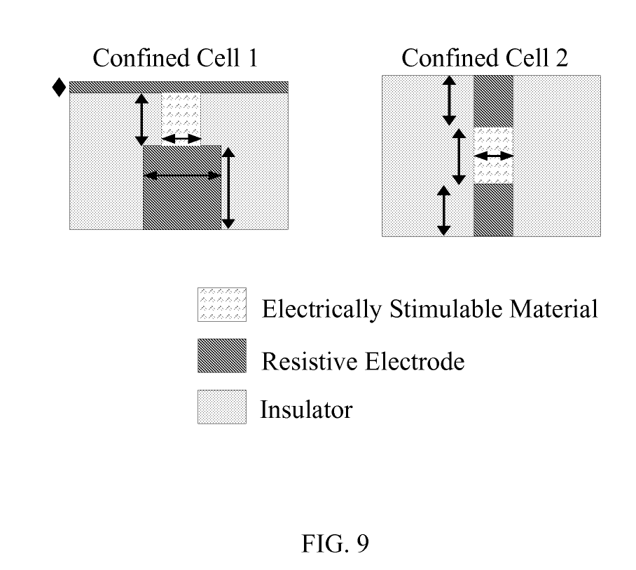

FIG. 9 shows two variations of the confined cell design. In the confined cell, the objective is to confine the volume of the electrically stimulable material to the smallest dimensions that permit resolution of the operable electrical states. Smaller dimensions require less energy for programming and external confinement by a surrounding insulator having a low thermal conductivity further improves efficiency by minimizing heat losses away from the region of programming. In other embodiments of the confined cell, the electrodes are also restricted in size to lower the current needed to resistively heat the electrode (Joule heating) to a temperature sufficient for programming. In a phase-change material, for example, programming to the reset state requires production of temperatures sufficient to melt the phase-change material. By confining the phase-change material and/or electrodes to smaller dimensions, the current density associated with a particular level of current increases and higher temperatures can be created at lower current levels. The instant CVD or ALD methods can be used to form confined volumes of either or both of the electrically stimulable material or resistive electrodes in the confined cell structure. Either or both of the lower or upper electrodes can be formed in a confined geometry using the methods of the instant invention.

The disclosure and discussion set forth herein is illustrative and not intended to limit the practice of the instant invention. While there have been described what are believed to be the preferred embodiments of the instant invention, those skilled in the art will recognize that other and further changes and modifications may be made thereto without departing from the spirit of the invention, and it is intended to claim all such changes and modifications that fall within the full scope of the invention. It is the following claims, including all equivalents, in combination with the foregoing disclosure and knowledge commonly available to persons of skill in the art, which define the scope of the instant invention.

We claim:

1. A method of forming an electronic device comprising:
providing an insulative layer having an opening defined therein, said opening having a sidewall;
vaporizing a first precursor, said first precursor comprising a metal and a first ligand, said first ligand comprising nitrogen;
delivering said vaporized first precursor to said opening; and
reacting or decomposing said vaporized first precursor to form a first electrode layer within said opening, said first electrode layer comprising said metal and said nitrogen, said first electrode layer conformally contacting said sidewall.

2. The method of claim 1, wherein said first ligand is an azide or hydrazine ligand.

3. The method of claim 2, wherein said first precursor further comprises a second ligand, said second ligand comprising nitrogen.

4. The method of claim 3, wherein said second ligand is an azide, hydrazine, amine or amide ligand.

5. The method of claim 2, wherein said first precursor further comprises a second ligand, said second ligand comprising silicon.

6. The method of claim 5, wherein said second ligand is a silylamine or aminosilyl ligand.

7. The method of claim 5, wherein said first electrode layer further comprises said silicon.

8. The method of claim 1, wherein said first ligand is an imine or imide ligand.

9. The method of claim 8, wherein said first precursor further comprises a second ligand, said second ligand comprising nitrogen.

10. The method of claim 9, wherein said second ligand is an azide, hydrazine, amine or amide ligand.

11. The method of claim 8, wherein said first precursor further comprises a second ligand, said second ligand comprising silicon.

12. The method of claim 11, wherein said second ligand is a silylamine or aminosilyl ligand.

13. The method of claim 1, wherein said metal is W, Ti or Ta.

14. The method of claim 1, wherein said metal is Nb, Mo, Pt, Cr, Co, or Ni

15. The method of claim 1, wherein said first electrode layer comprises a metal nitride compound.

16. The method of claim 1, wherein the atomic ratio of said nitrogen to said metal in said first electrode layer is greater than 1.

17. The method of claim 1, wherein the atomic ratio of said nitrogen to said metal in said first electrode layer is greater than 1.1.

18. The method of claim 1, wherein said first electrode layer fills said opening.

19. The method of claim 18, wherein said opening has an aspect ratio of at least 1:1.

20. The method of claim 18, wherein said opening has an aspect ratio of at least 3:1.

21. The method of claim 18, wherein a dimension of said opening is at the lithographic limit.

22. The method of claim 18, wherein a dimension of said opening is sublithographic.

23. The method of claim 18, wherein a dimension of said opening is less than 1000 Å.

24. The method of claim 18, wherein a dimension of said opening is less than 500 Å.

25. The method of claim 18, wherein a dimension of said opening is less than 300 Å.

26. The method of claim 1, further comprising
vaporizing a second precursor, said second precursor comprising aluminum;
delivering said vaporized second precursor to said opening, and
reacting or decomposing said vaporized second precursor in the presence of said vaporized first precursor to form said first electrode layer within said opening, said first electrode layer comprising said metal, said nitrogen, and said aluminum, said first electrode layer conformally contacting said sidewall.

27. The method of claim 26, wherein said second precursor is an alkyl aluminum precursor.

28. The method of claim 26, wherein said first electrode layer comprises a metal aluminum nitride compound.

29. The method of claim 1, further comprising
vaporizing a second precursor, said second precursor comprising silicon;
delivering said vaporized second precursor to said opening, and
reacting or decomposing said vaporized second precursor in the presence of said vaporized first precursor to form said first electrode layer within said opening, said first electrode layer comprising said metal, said nitrogen, and said silicon, said first electrode layer conformally contacting said sidewall.

30. The method of claim 29, wherein said first electrode layer comprises a metal silicon nitride compound.

31. The method of claim 1, further comprising
vaporizing a second precursor, said second precursor comprising oxygen;
delivering said vaporized second precursor to said opening, and
reacting or decomposing said vaporized second precursor in the presence of said vaporized first precursor to form said first electrode layer within said opening, said first electrode layer comprising said metal, said nitrogen, and said oxygen, said first electrode layer conformally contacting said sidewall.

32. The method of claim 31, wherein said first electrode layer comprises a metal oxynitride compound.

33. The method of claim 1, further comprising
terminating said delivery of said vaporized first precursor;
vaporizing a second precursor, said second precursor comprising aluminum;
delivering said vaporized second precursor to said opening, and
reacting or decomposing said vaporized second precursor in the presence of said first electrode layer, said reaction or decomposition causing the incorporation of said aluminum in said first electrode layer.

34. The method of claim 1, further comprising
terminating said delivery of said vaporized first precursor;
vaporizing a second precursor, said second precursor comprising silicon;
delivering said vaporized second precursor to said opening, and
reacting or decomposing said vaporized second precursor in the presence of said first electrode layer, said reaction or decomposition causing the incorporation of said silicon in said first electrode layer.

35. The method of claim 1, further comprising
terminating said delivery of said vaporized first precursor;
vaporizing a second precursor, said second precursor comprising oxygen;
delivering said vaporized second precursor to said opening, and
reacting or decomposing said vaporized second precursor in the presence of said first electrode layer, said reaction or decomposition causing the incorporation of said oxygen in said first electrode layer.

36. The method of claim 1, wherein the depth of said opening is equal to the thickness of said insulative layer.

37. The method of claim 36, wherein said insulating layer is formed over a second electrode layer, said opening exposing a top surface of said second electrode layer, said first electrode layer conformally contacting said exposed portion of said second electrode layer.

38. The method of claim 1, further comprising forming an electrically stimulable material over said first electrode layer.

39. The method of claim 38, wherein said electrically stimulable material is selected from the group consisting of non-volatile memory materials, programmable resistance materials, electronic switching materials, chalcogenide materials, phase-change materials, and pnictide materials.

40. The method of claim 38, wherein said electrically stimulable material is formed by chemical vapor deposition or atomic layer deposition.

41. The method of claim 38, wherein said electrically stimulable material comprises Te and Sb.
